(19) United States
(12) Patent Application Publication
(10) Pub. No.: US 2024/0380172 A1
(43) Pub. Date: Nov. 14, 2024

(54) LIGHT-EMITTING DEVICE AND LIGHT-EMITTING MODULE

(71) Applicants: NICHIA CORPORATION, Anan-shi (JP); FURUKAWA ELECTRIC CO., LTD., Tokyo (JP)

(72) Inventors: Takashi NAMIE, Anan-shi (JP); Kazuma KOZURU, Anan-shi (JP)

(73) Assignees: NICHIA CORPORATION, Anan-shi, Tokushima (JP); FURUKAWA ELECTRIC CO., LTD., Tokyo (JP)

(21) Appl. No.: 18/652,513

(22) Filed: May 1, 2024

(30) Foreign Application Priority Data
May 10, 2023 (JP) 2023-078150

(51) Int. Cl. H01S 5/02255; H01S 5/02251; H01S 5/02253; H01S 5/40

(52) U.S. Cl. CPC H01S 5/02255; H01S 5/02251; H01S 5/02253; H01S 5/4012; H01S 5/4031

(57) ABSTRACT

A light-emitting device includes a substrate having a mounting surface, a semiconductor laser element supported by the mounting surface, a first mirror member supported by the mounting surface and having a first reflective surface, and a second mirror member supported by a support member and spaced apart from the first mirror member, and having a second reflective surface at least a part of which is positioned above at least a part of the first reflective surface. The semiconductor laser element is configured to emit a laser beam toward the first reflective surface in a first direction, the first reflective surface reflects the laser beam to change a traveling direction of the laser beam to a second direction, and the second reflective surface reflects the laser beam reflected by the first reflective surface to change the traveling direction of the laser beam to a third direction.

### CROSS-REFERENCE TO RELATED APPLICATIONS

The present application claims priority under 35 U.S.C. § 119 to Japanese Patent Application No. 2023-078150, filed May 10, 2023, the contents of which is hereby incorporated by reference in its entirety.

### BACKGROUND

### 1. Technical Field

The present disclosure relates to a light-emitting device and a light-emitting module.

### 2. Description of Related Art

In recent years, a light-emitting module that combines a plurality of laser beams emitted from a plurality of semiconductor laser elements to increase a laser beam output has been developed. Japanese Patent Publication No. 2016-62918 discloses an example of such a light-emitting module.

In the case of manufacturing a light-emitting module by arranging a plurality of semiconductor laser packages, each accommodating a semiconductor laser element, limitations exist in the miniaturization of the light-emitting module due to the configuration of each semiconductor laser package.

### SUMMARY

Miniaturization of a light-emitting module using a plurality of semiconductor laser packages has been required. Hereinafter, a structure that emits a laser beam using a semiconductor laser element, such as a semiconductor laser package, is referred to as a “light-emitting device.”

In an embodiment, a light-emitting device of the present disclosure includes: a substrate having a mounting surface; a semiconductor laser element supported by the mounting surface; a first mirror member supported by the mounting surface and having a first reflective surface inclined with respect to the mounting surface and facing obliquely upward; and a second mirror member supported by a support member such that the second mirror member is spaced apart from the first mirror member, the second mirror member having a second reflective surface at least a part of which is positioned above at least a part of the first reflective surface. In the light-emitting device, the semiconductor laser element is disposed such that the semiconductor laser element is configured to emit a laser beam toward the first reflective surface in a first direction, the first reflective surface reflects the laser beam to change a traveling direction of the laser beam to a second direction away from the mounting surface of the substrate, and the second reflective surface reflects the laser beam reflected by the first reflective surface to change the traveling direction of the laser beam to a third direction that intersects a plane including both a straight line extending in the first direction and a straight line extending in the second direction.

In an embodiment, a light-emitting module of the present disclosure includes: a plurality of light-emitting devices arranged side by side in the third direction and disposed such that the plurality of light-emitting devices are shifted stepwise in a direction same as or opposite to the first direction, each of the plurality of light-emitting devices being the above light-emitting device; and a condensing lens configured to combine a plurality of laser beams obtained when the laser beam is emitted from each of the plurality of light-emitting devices in the third direction.

In an embodiment, a light-emitting module of the present disclosure includes: a plurality of first light-emitting devices disposed at different positions in one direction, each of the plurality of light-emitting devices being the above light-emitting device that is configured to emit a first laser beam in a direction parallel to the one direction; a plurality of second light-emitting devices disposed at different positions in another direction, each of the plurality of light-emitting devices being the above light-emitting device that is configured to emit a second laser beam in a direction parallel to the another direction; a third mirror member having a third reflective surface, the third reflective surface being configured to reflect a plurality of first laser beams obtained when the first laser beam is emitted from each of the plurality of first light-emitting devices; a fourth mirror member having a fourth reflective surface, the fourth reflective surface being configured to reflect a plurality of second laser beams obtained when the second laser beam is emitted from each of the plurality of second light-emitting devices; and a condensing lens configured to combine the plurality of first laser beams reflected by the third reflective surface and the plurality of second laser beams reflected by the fourth reflective surface.

According to an embodiment of the present disclosure, in a light-emitting module using a plurality of light-emitting devices, the light-emitting devices that can miniaturize the light-emitting module can be implemented.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1A is a perspective view schematically illustrating a configuration of a light-emitting module according to a first exemplary embodiment of the present disclosure.

FIG. 1B is a top view schematically illustrating the configuration of the light-emitting module according to the first exemplary embodiment of the present disclosure.

FIG. 2A is a perspective view schematically illustrating a configuration of a light-emitting device according to the first exemplary embodiment of the present disclosure.

FIG. 2B is an exploded perspective view of the light-emitting device illustrated in FIG. 2A.

FIG. 2C is another exploded perspective view of the light-emitting device illustrated in FIG. 2A.

FIG. 2D is a perspective view of a frame body included in the light-emitting device illustrated in FIG. 2C, as viewed from below.

FIG. 2E is a top view of the configuration of the light-emitting device illustrated in FIG. 2A when a second mirror member, a slow-axis collimating lens, and a cover are omitted.

FIG. 2F is a cross-sectional view parallel to a YZ plane of the configuration of the light-emitting device illustrated in FIG. 2A when the second mirror member and the slow-axis collimating lens are omitted.

FIG. 2G is another cross-sectional view parallel to the YZ plane of the configuration of the light-emitting device illustrated in FIG. 2A when the second mirror member and the slow-axis collimating lens are omitted.

FIG. 2H is a schematic side view of the light-emitting device illustrated in FIG. 2A, as seen along a +Z direction.

FIG. 3A is a side view schematically illustrating a configuration of a first modified example of the light-emitting device according to the first embodiment, as seen along the +Z direction.

FIG. 3B is a side view schematically illustrating a configuration of a second modified example of the light-emitting device according to the first embodiment, as seen along the +Z direction.

FIG. 4 is a top view schematically illustrating a configuration of a light-emitting module according to a second exemplary embodiment of the present disclosure.

FIG. 5 is a top view schematically illustrating a modified example of the light-emitting module according the second embodiment.

FIG. 6A is an exploded perspective view of a laser light source.

FIG. 6B is a cross-sectional view parallel to the YZ plane of the laser light source.

### DETAILED DESCRIPTION

### Description of Embodiments

A light-emitting device according to an embodiment of the present disclosure and a light-emitting module including a plurality of the light-emitting devices are described below with reference to the drawings. Parts having the same reference numerals appearing in the plurality of drawings indicate identical or equivalent parts.

The embodiments described below embody the technical ideas of the present invention, but the present invention is not limited to the described embodiments. The descriptions of sizes, materials, shapes, relative arrangements, and the like of components are not intended to limit the scope of the present invention thereto but intended to be illustrative. The sizes and positional relationships of members illustrated in the drawings may be exaggerated to facilitate understanding.

In the present specification or the scope of claims, polygons such as triangles or quadrangles, including shapes in which the corners of the polygons are rounded, chamfered, beveled, or coved, are referred to as polygons. A shape obtained by processing not only the corners (ends of sides), but also an intermediate portion of a side is also referred to as a polygon. In other words, a shape partially processed while leaving a polygon shape as a base is included in the interpretation of “polygon” described in the present specification and the scope of claims.

In the present disclosure, the term “parallel” includes, unless otherwise stated, a case in which an angle formed between two straight lines, sides, surfaces, or the like is in a range from 0° to 5°. In the present disclosure, the terms “perpendicular” and “orthogonal” include, unless otherwise stated, a case in which an angle formed between two straight lines, sides, surfaces, or the like is in a range of +5° from 90°.

### First Embodiment

### Light-Emitting Module

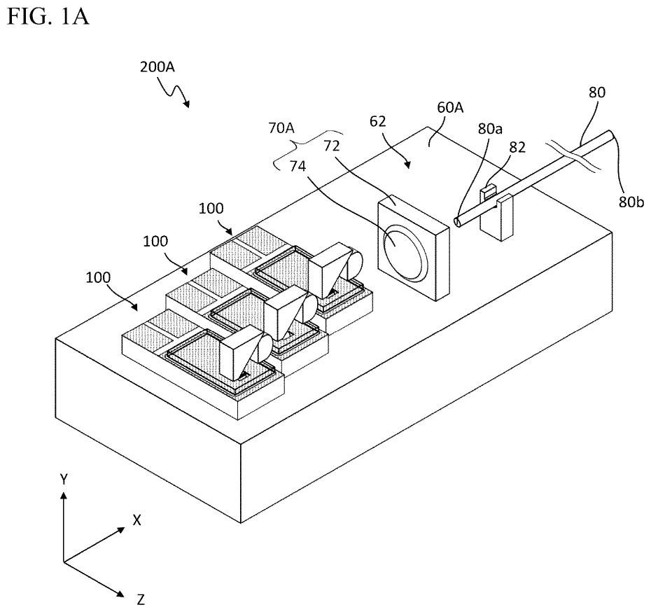

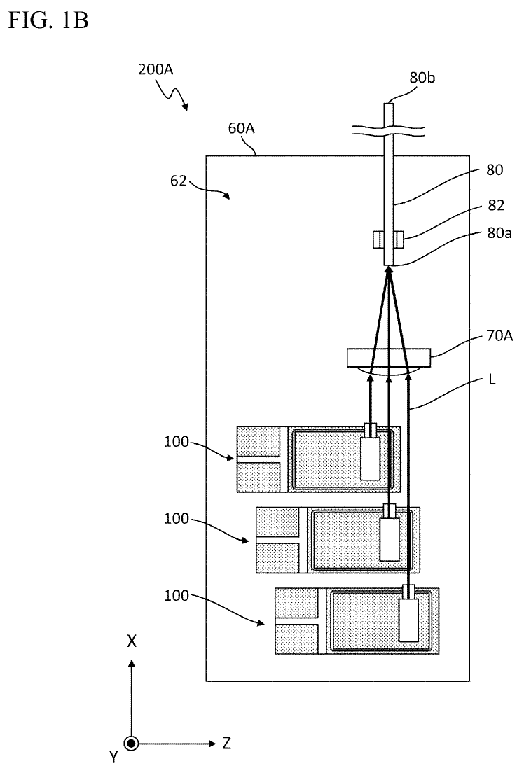

First, a configuration example of a light-emitting module according to a first embodiment of the present disclosure is described with reference to FIGS. 1A and 1B. FIGS. 1A and 1B are a perspective view and a top view schematically illustrating the configuration of the light-emitting module according to the first exemplary embodiment of the present disclosure, respectively. A light-emitting module 200A illustrated in FIGS. 1A and 1B emits a high-power laser beam as described below.

These drawings schematically illustrate an X-axis, a Y-axis, and a Z-axis that are orthogonal to one another for reference. The direction of an arrow on the X-axis is referred to as a +X direction, and an opposite direction thereof is referred to as a −X direction. When the +X directions are not distinguished, the #X directions are simply referred to as X directions. The same applies to a Y direction and a Z direction. In the present specification, for ease of description, the +Y direction is referred to as “upward” and the −Y direction is referred to as “downward.” This does not limit the orientation of the light-emitting module during use, and the orientation of the light-emitting module is arbitrary.

As illustrated in FIGS. 1A and 1B, the light-emitting module 200A includes a support base 60A, a condensing lens 70A, and a plurality of light-emitting devices 100. As illustrated in FIGS. 1A and 1B, the light-emitting module 200A may further include an optical fiber 80 and a support member 82 that supports the optical fiber 80.

The support base 60A has a support surface 62. The support surface 62 directly supports the condensing lens 70A and the plurality of light-emitting devices 100, and supports the optical fiber 80 via the support member 82. The support surface 62 may also support the condensing lens 70A and/or the plurality of light-emitting devices 100 via another member. The support surface 62 is parallel to a XZ plane. When the support surface 62 is divided into a first region that supports the plurality of light-emitting devices 100 and a second region that supports the condensing lens 70A and the optical fiber 80, the first and second regions may be or need not be positioned on the same plane.

In the example illustrated in FIGS. 1A and 1B, the number of light-emitting devices 100 is three, but is not limited to this number. The number of light-emitting devices 100 may be two, or four or more. As the number of light-emitting devices 100 increases, a high-power laser beam can be obtained more easily in the light-emitting module 200A.

The support base 60A may be formed of a ceramic selected from the group consisting of AlN, SiN, SiC, and alumina, for example. The support base 60A may be formed of at least one metal material selected from the group consisting of Cu, Al, and Ag, for example. The support base 60A may be formed of a metal matrix composite material obtained by dispersing diamond particles in at least the one metal material selected from the group consisting of Cu, Al, and Ag, for example.

The support base 60A is preferably formed of a metal material selected from the group consisting of Cu, Al, Ag, and the like, and is preferably composed of a single member. This is because the metal material has heat dissipation superior to that of a ceramic and is soft and easy to process.

The support base 60A functions as a support on which the plurality of light-emitting devices 100 are disposed. The support base 60A can also function as a heat sink that transfers heat generated from the plurality of light-emitting devices 100 to the outside, thus reducing an excessive temperature rise of the light-emitting devices 100. In this case, one or a plurality of channels for liquid cooling may be provided inside the support base 60A. A liquid that can be used for the liquid cooling includes water. A fin structure for air cooling may be provided on the surface of the support base 60A. Alternatively, when the support base 60A is disposed on a separately prepared heat sink, the support base 60A can also function as a heat spreader that transfers the heat generated from the plurality of light-emitting devices 100 to the heat sink.

The plurality of light-emitting devices 100 are arranged side by side in the X direction and are disposed at different positions in the Z direction on the support surface 62 that is the same plane. In the example illustrated in FIGS. 1A and 1B, the plurality of light-emitting devices 100 are arranged side by side in the +X direction, and are disposed on the support surface 62 such that they are shifted stepwise in the −Z direction. The shift direction need not be the −Z direction, but rather may be the +Z direction, which is an opposite direction thereof. Alternatively, the plurality of light-emitting devices 100 may be arranged side by side in the X-direction and disposed irregularly in the Z-direction.

Although details of the structure of each light-emitting device 100 are described below, each light-emitting device 100 includes a semiconductor laser element therein. In the XZ plane parallel to the support surface 62, the direction in which each light-emitting device 100 has the largest size is the Z direction, and the direction in which each light-emitting device 100 has the smallest size is the X direction. Laser light emitted from the semiconductor laser element of each light-emitting device 100 is extracted to the outside of the light-emitting device 100. As a result, each light-emitting device 100 emits a laser beam L in the +X direction from above a space accommodating the semiconductor laser element, as illustrated in FIG. 1B. The thick arrow illustrated in FIG. 1B indicates the traveling direction of the laser beam L. The laser beam L is a beam collimated in the XY plane and the XZ plane, and an optical axis of the laser beam Lis a central axis of the beam. The emission direction of the laser beam L intersects, more specifically is orthogonal to, the direction in which each light-emitting device 100 has the largest size in the XZ plane.

The plurality of light-emitting devices 100 each having such a configuration are disposed as described above, so that when the traveling direction of the laser beam Lis defined as a forward direction, the laser beam L emitted from each of the light-emitting devices 100 other than the light-emitting device 100 positioned on the foremost side travels above the light-emitting device 100 disposed further forward without hitting the light-emitting device 100 disposed further forward, as illustrated in FIG. 1B.

Therefore, the plurality of light-emitting devices 100 need not be disposed at different heights so that the laser beams L do not interfere with one another. As illustrated in FIGS. 1A and 1B, the plurality of light-emitting devices 100 can be disposed on the same plane even without providing a step on the support surface 62 of the support base 60A. Because the laser beam L emitted from each of the light-emitting devices 100 other than the light-emitting device 100 positioned on the foremost side is disposed so as to travel above the light-emitting device 100 disposed further forward, the light-emitting module 200A can be miniaturized and a distance between optical axes of the plurality of laser beams L can be narrowed. The plurality of laser beams L are obtained by emitting the laser beam L from each of the plurality of light-emitting devices 100. In the present specification, “the distance between the optical axes of the plurality of laser beams L” refers to a distance between the optical axes of any two laser beams L adjacent to each other among the plurality of laser beams L. With the support surface 62 as a height reference, the heights of the optical axes of the plurality of laser beams L are equal to one another. In the present specification, “the heights of the optical axes of the plurality of laser beams L are equal to one another” means that a difference between the height of the highest optical axis and the height of the lowest optical axis among the heights of the optical axes of the plurality of laser beams Lis within 1 mm.

The plurality of light-emitting devices 100 are disposed on the same plane, thereby reducing variations in the amount of heat generated from the plurality of light-emitting devices 100 and transferred to the plane on which the support base 60A is disposed. When the support base 60A includes therein a channel extending in the X direction below the support surface 62, flowing a liquid into the channel allows variations in the degree of cooling of the plurality of light-emitting devices 100 to be reduced. Therefore, the light-emitting module 200A can improve the efficiency of heat dissipation from the plurality of light-emitting devices 100.

Because the distance between the optical axes of the plurality of laser beams L is narrow, the size in the Z direction of the condensing lens 70A that receives all of the plurality of laser beams L can be reduced accordingly.

As illustrated in FIG. 1A, the condensing lens 70A includes a flat plate portion 72 and a spherical convex lens portion 74 protruding from the flat plate portion 72. The convex lens portion 74 has an optical axis parallel to the X direction, and causes light incident parallel to the optical axis to converge at a focal point of the convex lens portion 74. The condensing lens 70A is disposed such that the focal point of the convex lens portion 74 substantially coincides with a light-incident end 80a of the optical fiber 80. As illustrated in FIG. 1B, the condensing lens 70A causes the plurality of laser beams L traveling in the +X direction to converge at the light-incident end 80a of the optical fiber 80. In this way, the condensing lens 70A can combine the plurality of laser beams L and cause the combined laser beams to enter the optical fiber 80. The optical fiber 80 guides the plurality of laser beams L combined by the condensing lens 70A and emits the laser beams L from a light-emitting end 80b.

Instead of the single condensing lens 70A, a fast-axis condensing lens and a slow-axis condensing lens may be used. The fast-axis condensing lens is a cylindrical lens having a uniform cross-sectional shape in the Y direction, and the slow-axis condensing lens is a cylindrical lens having a uniform cross-sectional shape in the Z direction. An example of using the fast-axis condensing lens and the slow-axis condensing lens is described below.

The condensing lens 70A may be formed of at least one light-transmissive material selected from the group consisting of glass, silicon, quartz, synthetic quartz, sapphire, transparent ceramics, silicone resin, and plastic.

As described above, the light-emitting module 200A emits combined light obtained by combining the plurality of laser beams L from the light-emitting end 80b of the optical fiber 80. The output of the combined light is approximately equal to a value obtained by multiplying the output of the laser beam L emitted from each of the light-emitting devices 100 by the number of light-emitting devices 100 and the combining efficiency. Therefore, when the number of light-emitting devices 100 is increased, the output of the combined light can be increased.

In the light-emitting module 200A, when the traveling directions of some or all of the laser beams L among the plurality of laser beams L deviate from the designed +X direction, even though the deviation angle is about several degrees, there is a possibility that the plurality of laser beams L may not be effectively combined and the output of the combined light may be reduced.

As described below, the light-emitting device 100 makes it possible to reduce the deviation between the traveling direction of the laser beam L emitted to the outside from the light-emitting device 100 and the +X direction being the designed traveling direction. An angle formed between the traveling direction of the laser beam L and the designed traveling direction is preferably equal to or less than 1°, more preferably equal to or less than 0.1º, for example.

### Light-Emitting Device

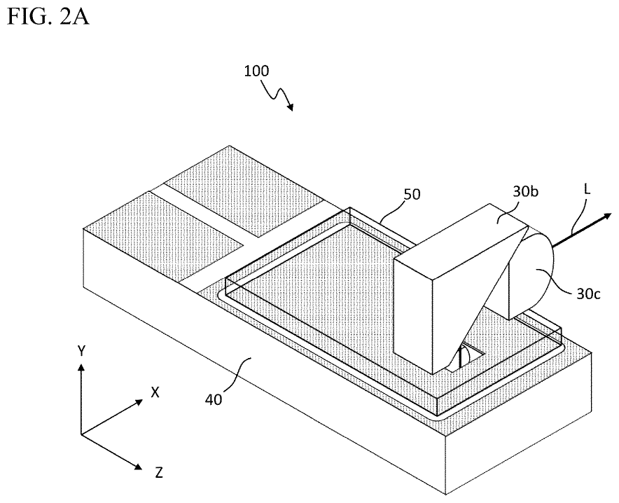

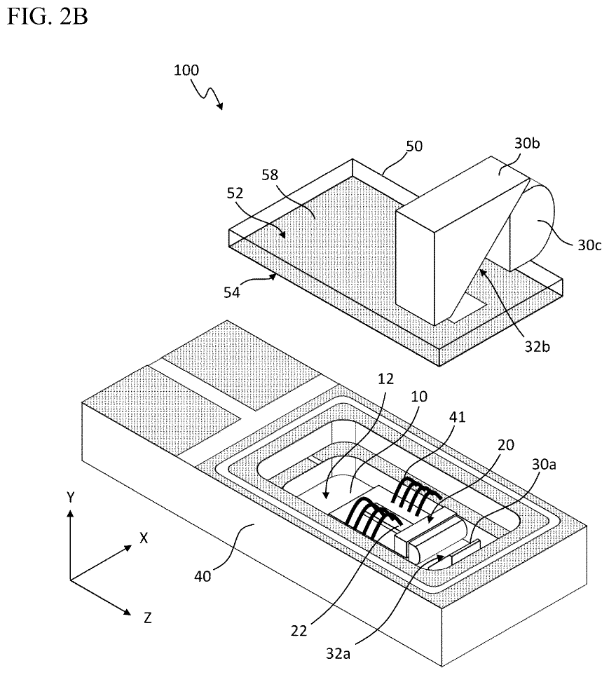

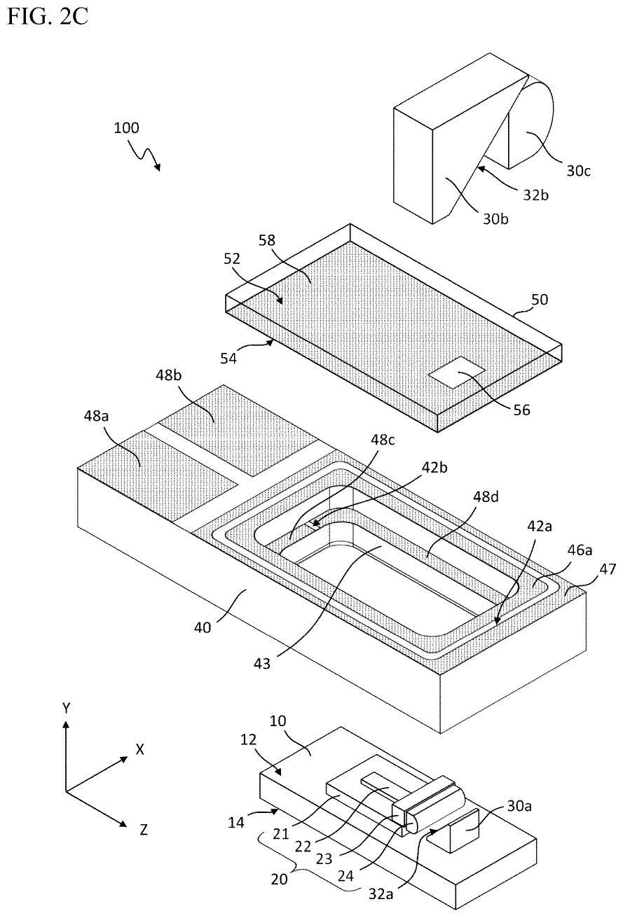

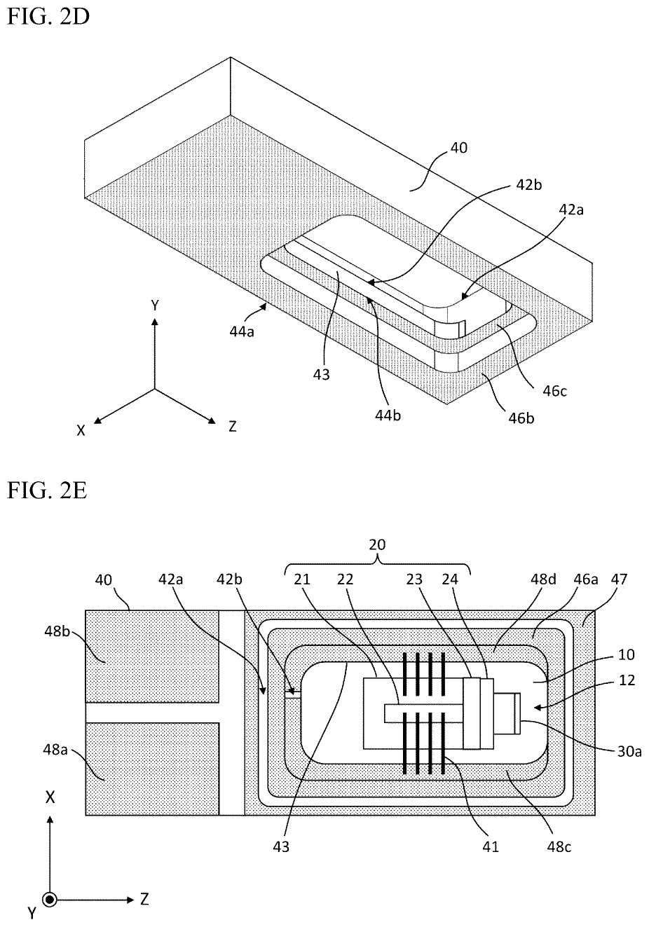

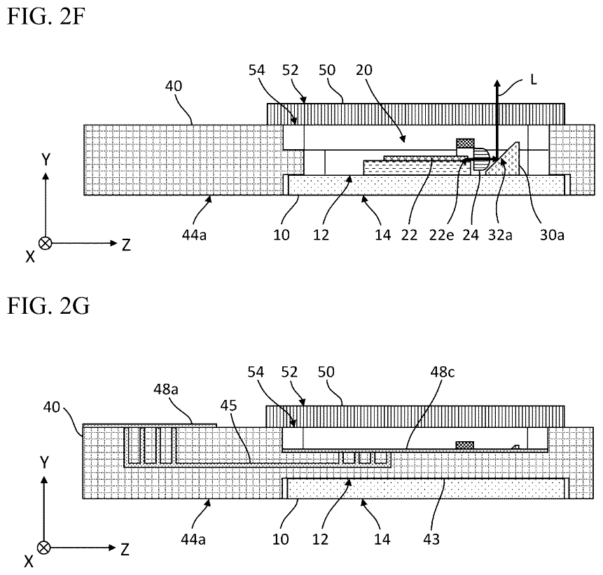

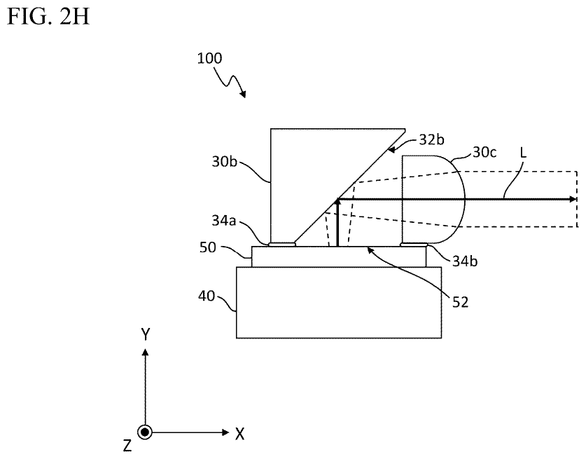

A configuration example of a light-emitting device according to a first embodiment of the present disclosure is described below with reference to FIGS. 2A and 2B. FIG. 2A is a perspective view schematically illustrating the configuration of the light-emitting device according to the exemplary first embodiment of the present disclosure. FIG. 2B is an exploded perspective view of the light-emitting device illustrated in FIG. 2A. In the first embodiment, the light-emitting device 100 illustrated in FIGS. 2A and 2B is employed in the light-emitting module 200A illustrated in FIGS. 1A and 1B, but the light-emitting device 100 may be employed in a more general spatial coupling type light-emitting module. The light-emitting device 100 may be employed in other devices such as lighting devices instead of being employed in a light-emitting module.

As illustrated in FIG. 2B, the light-emitting device 100 includes a substrate 10, a laser light source 20, a first mirror member 30a, and a second mirror member 30b. As illustrated in FIG. 2B, the light-emitting device 100 may further include a slow-axis collimating lens 30c, a frame body 40, a plurality of wires 41, and a cover 50. The first mirror member 30a has a first reflective surface 32a, and the second mirror member 30b has a second reflective surface 32b. The laser light source 20 is a chip-on-submount semiconductor laser light source including a semiconductor laser element 22. The light-emitting device 100 may further include a protective element such as a Zener diode, and/or a temperature measuring element for measuring an internal temperature such as a thermistor.

FIG. 2C is another exploded perspective view of the light-emitting device 100 illustrated in FIG. 2A. In FIG. 2C, the plurality of wires 41 illustrated in FIG. 2B are omitted. FIG. 2D is a perspective view of the frame body 40 included in the light-emitting device 100 illustrated in FIG. 2C, as viewed from below. FIG. 2E is a top view of the configuration of the light-emitting device 100 illustrated in FIG. 2A when the second mirror member 30b, the slow-axis collimating lens 30c, and the cover 50 are omitted. FIGS. 2F and 2G are cross-sectional views parallel to the YZ plane of the configuration of the light-emitting device 100 illustrated in FIG. 2A when the second mirror member 30b and the slow-axis collimating lens 30c are omitted. The cross-sectional view of FIG. 2F intersects the laser light source 20, while the cross-sectional view of FIG. 2G does not intersect the laser light source 20. FIG. 2H is a schematic side view of the light-emitting device 100 illustrated in FIG. 2A, as seen along the +Z direction.

In the light-emitting device 100 according to the first embodiment, as illustrated in FIG. 2F, the laser beam L emitted from the laser light source 20 in the +Z direction is reflected in the +Y direction by the first reflective surface 32a. The laser beam L reflected in the +Y direction by the first reflective surface 32a is reflected in the +X direction by the second reflective surface 32b as illustrated in FIG. 2H. With such a configuration, the light-emitting device 100 can emit the laser beam L from above a space accommodating the semiconductor laser element 22. The emission direction of the laser beam L intersects, more specifically is orthogonal to, the direction in which the light-emitting device 100 has the largest size in the XZ plane. As a result, as described above, the plurality of light-emitting devices 100 can be disposed on the same plane such that the distance between the optical axes of the plurality of laser beams L is reduced.

In the light-emitting device 100 according to the first embodiment, by appropriately adjusting the position and orientation of the second mirror member 30b, the deviation between the laser beam L emitted to the outside from the light-emitting device 100 and the +X direction being the designed traveling direction can be reduced. As a result, in the light-emitting module 200A, the plurality of laser beams L traveling in the +X direction can be effectively combined by the condensing lens 70A, and high-power combined light can be output.

In the present specification, the traveling direction of the laser beam L emitted from the laser light source 20 is also referred to as a “first direction,” the traveling direction of the laser beam L reflected by the first reflective surface 32a is also referred to as a “second direction,” and the traveling direction of the laser beam L reflected by the second reflective surface 32b is also referred to as a “third direction.” In the first embodiment, the first direction is the +Z direction, the second direction is the +Y direction, and the third direction is the +X direction; however, the present disclosure is not limited to these three directions. The first direction and the second direction may be or need not be orthogonal to each other as long as the first direction and the second direction intersect with each other. As long as the third direction intersects a plane including both a straight line extending in the first direction and a straight line extending in the second direction, the third direction may be or need not be orthogonal to the plane.

Each of the components of the light-Emitting Device 100 is described below.

### Substrate 10

As illustrated in FIG. 2C, the substrate 10 has a mounting surface 12 and a lower surface 14. The normal direction of the mounting surface 12 is the +Y direction. In the present specification, the normal direction of a surface means a direction perpendicular to the surface and away from an object having the surface. In the example illustrated in FIG. 2C, the substrate 10 has a rectangular flat plate shape, but is not limited to this shape. The substrate 10 may have a polygonal, a circular, or an elliptical flat plate shape, for example. The lower surface 14 of the substrate 10 is bonded to the support surface 62 of the support base 60A via, for example, an inorganic bonding member such as a solder material.

The substrate 10 may be formed of a material having a thermal conductivity in a range from 10 W/m·K to 2000 W/m·K, for example. Due to the substrate 10 having such a high thermal conductivity, heat generated from the laser light source 20 during driving can be effectively transferred to the support base 60A illustrated in FIGS. 1A and 1B via the substrate 10. The substrate 10 may be formed of the same material as the support base 60A, for example. The size of the substrate 10 in the X direction may be in a range from 1 mm to 10 mm, for example, the size thereof in the Y direction may be in a range from 0.1 mm to 5 mm, for example, and the size thereof in the Z direction may be in a range from 1 mm to 20 mm, for example.

### Laser Light Source 20

As illustrated in FIG. 2C, the laser light source 20 is supported by the mounting surface 12 of the substrate 10. The laser light source 20 includes a submount 21, an end-surface emission type semiconductor laser element 22 supported by the submount 21, a lens support member 23, and a fast-axis collimating lens 24. The semiconductor laser element 22 is supported by the mounting surface 12 of the substrate 10 via the submount 21. The semiconductor laser element 22 is disposed such that it emits the laser beam L toward the first reflective surface 32a. The lens support member 23 has a shape straddling the semiconductor laser element 22. The fast-axis collimating lens 24 is supported by an end surface of the lens support member 23. The components of the laser light source 20 may be treated as components of the light-emitting device 100.

The semiconductor laser element 22 emits the laser beam L from an emission surface. The emission surface is a plane extending in the X direction and parallel to the XY plane. In this case, the laser beam L emitted from the semiconductor laser element 22 in the +Z direction diverges relatively fast in the YZ plane and diverges relatively slowly in the XZ plane. The fast axis direction of the laser beam L is parallel to the Y direction, and the slow axis direction is parallel to the X direction. The laser beam L emitted from the semiconductor laser element 22 has an elliptical shape having a major axis in the Y direction and a minor axis in the X direction in the XY plane.

The fast-axis collimating lens 24 is disposed such that the focal point of the fast-axis collimating lens 24 substantially coincides with the center of a light emission point of the emission surface of the semiconductor laser element 22. The fast-axis collimating lens 24 collimates the laser beam L emitted in the +Z direction from the semiconductor laser element 22, in the fast axis direction in the YZ plane. In the present specification, the term “collimating” refers to not only causing the laser beam L to be parallel light but also reducing the divergence angle of the laser beam L.

From the above, the laser light source 20 emits the laser beam L from the fast-axis collimating lens 24 in the +Z direction. The laser beam L emitted from the laser light source 20 is collimated in the YZ plane, but is not collimated in the XZ plane. A specific configuration of the laser light source 20 is described below.

As illustrated in FIG. 2F, the semiconductor laser element 22 included in the laser light source 20 is sealed by the substrate 10, the frame body 40, and the cover 50. This seal is preferably a hermetic seal. The effect of the hermetic seal increases as the wavelength of the laser beam L emitted from the semiconductor laser element 22 decreases.

This is because, in a configuration having the emission surface of the semiconductor laser element 22 that is not hermetically sealed and is exposed to the outside air, the shorter the wavelength of the laser beam Lis, the higher the possibility that deterioration of the emission surface may progress due to dust collecting during operation is.

Instead of the end-surface emission type semiconductor laser element 22, a surface-emitting type semiconductor laser element, such as a vertical-cavity surface-emitting laser (VCSEL) element, may also be used. The surface-emitting type semiconductor laser element is disposed such that a laser beam emitted from the semiconductor laser element travels in the +Z direction.

### First Mirror Member 30a and Second Mirror Member 30b

As illustrated in FIG. 2C, the first mirror member 30a is supported by the mounting surface 12 of the substrate 10. The first mirror member 30a has a uniform cross-sectional shape in the X direction. The cross-sectional shape is substantially triangular. The first mirror member 30a has a lower surface, a back surface, and an inclined surface joining the lower surface and the back surface. The lower surface is parallel to the XZ plane and the back surface is parallel to the XY plane. The normal direction of the inclined surface is a direction that is parallel to the YZ plane, forms an acute angle with the +Y direction, and forms an acute angle with the −Z direction. An angle formed between the lower surface and the inclined surface of the first mirror member 30a is 45°, but is not limited to this angle, and may be in a range from 30° to 60°, for example.

The first mirror member 30a has, on the above inclined surface thereof, the first reflective surface 32a having a planar shape. The first reflective surface 32a is inclined with respect to the mounting surface 12 of the substrate 10 and faces obliquely upward. In the present specification, “obliquely upward” means a direction forming an angle in a range from 30° to 60° with the +Y direction. The normal direction of the first reflective surface 32a may be or need not be parallel to the YZ plane as long as the first reflective surface 32a can receive the laser beam L emitted from the laser light source 20 and the normal direction of the first reflective surface 32a is a direction forming an angle in a range from 30° to 60° with the +Y direction.

As illustrated FIG. 2F, the first reflective surface 32a reflects the laser beam L emitted from the laser light source 20 to change the traveling direction of the laser beam L to a direction away from the mounting surface 12 of the substrate 10. An angle formed between the traveling direction of the laser beam L being the direction away from the mounting surface 12 of the substrate 10 and the normal direction of the mounting surface 12 may be in a range from 0° to 5°, for example. Because this angle has a tolerance of 5°, the position and orientation of the first mirror member 30a need not be adjusted with as much precision as the position and orientation of the second mirror member 30b.

As illustrated in FIG. 2B, the second mirror member 30b is supported by an upper surface 52 of the cover 50 so as to be spaced apart from the first mirror member 30a. The second mirror member 30b has a uniform cross-sectional shape in the Z direction. The cross-sectional shape is substantially trapezoidal. The second mirror member 30b has an upper surface, a lower surface, and an inclined surface connecting the upper surface and the lower surface. Each of the upper surface and the lower surface is parallel to the XZ plane. The size of the lower surface in the Z direction is equal to the size of the upper surface in the Z direction. On the other hand, the size of the lower surface in the X direction is smaller than the size of the upper surface in the X direction. The normal direction of the inclined surface is a direction that is parallel to the XY plane, forms an acute angle with the +X direction, and forms an acute angle with the −Y direction. An angle formed between the upper surface and the inclined surface of the second mirror member 30b is 45°, but is not limited to this angle, and may be in a range from 30° to 60°, for example. The angle formed between the upper surface and the inclined surface of the second mirror member 30b may be equal to or different from the angle formed between the lower surface and the inclined surface of the first mirror member 30a.

The second mirror member 30b has, on the above inclined surface thereof, the second reflective surface 32b having a planar shape. At least a part of the second reflective surface 32b is positioned above at least a part of the first reflective surface 32a. As illustrated in FIG. 2H, the second reflective surface 32b reflects the laser beam L reflected by the first reflective surface 32a to change the traveling direction of the laser beam L to the +X direction. The traveling direction of the laser beam L reflected by the second reflective surface 32b in the +X direction intersects, more specifically is orthogonal to, the traveling direction of the laser beam L emitted from the laser light source 20 in the +Z direction.

The traveling direction of the laser beam L reflected by the second reflective surface 32b is changed and the shape of the laser beam L becomes an elliptical shape having a major axis in the Y direction and a minor axis in the Z direction in the YZ plane. In the example illustrated in FIG. 1B, the plurality of light-emitting devices 100 are disposed such that they are shifted stepwise in the −Z direction. In this example, the shape of the laser beam L reflected by the second reflective surface 32b is an elliptical shape having a minor axis in the Z direction in the YZ plane. Therefore, the plurality of light-emitting devices 100 can be disposed with a small amount of shift, and as a result, the light-emitting module 200A can be miniaturized.

The laser beam L emitted from the laser light source 20 is reflected by the first reflective surface 32a and the second reflective surface 32b in this order. As a result, as described above, the light-emitting device 100 can emit the laser beam L from above the space accommodating the semiconductor laser element 22. The emission direction of the laser beam L intersects, more specifically is orthogonal to, the direction in which the light-emitting device 100 has the largest size in the XZ plane.

As illustrated in FIG. 2H, a first resin layer 34a exists between the lower surface of the second mirror member 30b and the upper surface 52 of the cover 50. The first resin layer 34a is formed by curing uncured resin in a state in which the lower surface of the second mirror member 30b is in contact with the upper surface 52 of the cover 50 via the resin. The resin may be, for example, a thermosetting resin that is cured by heating, or a photocurable resin that is cured by irradiation with ultraviolet rays or visible light. Before the resin is cured, the following active alignment is performed. That is, the position and orientation of the second mirror member 30b are appropriately adjusted such that the second reflective surface 32b changes the traveling direction of the laser beam L to the +X direction with the laser light source 20 emitting the laser beam L. Such an adjustment can be performed while holding the second mirror member 30b using a holding device after the light-emitting device 100 is disposed on the support surface 62 of the support base 60A illustrated in FIGS. 1A and 1B. In this way, the deviation between the traveling direction of the laser beam L emitted to the outside from the light-emitting device 100 and the +X direction being the designed traveling direction can be reduced.

Before the resin is cured, by rotating the second mirror member 30b about the Y-axis or the Z-axis as a rotation axis to adjust the orientation of the second mirror member 30b, the traveling direction of the laser beam L can be adjusted. Rotating the second mirror member 30b about the Z-axis as the rotation axis can change the traveling direction of the laser beam L up and down. Rotating the second mirror member 30b about the Y-axis as the rotation axis can change the traveling direction of the laser beam L from side to side, with the traveling direction of the laser beam L being a front direction.

Before the resin is cured, by adjusting the position of the second mirror member 30b in the X direction, the height of the optical axis of the laser beam L can be adjusted. The height of the optical axis of the laser beam L can be reduced by shifting the second mirror member 30b in the +X direction, and the height of the optical axis of the laser beam L can be increased by shifting the second mirror member 30b in the −X direction.

Unlike in the light-emitting device 100 according to the first embodiment, when the second mirror member 30b is fixed to the upper surface 52 of the cover 50 without adjusting the position and orientation of the second mirror member 30b, the traveling direction of the laser beam L reflected by the second reflective surface 32b is not necessarily parallel to the +X direction in some cases. Even with such a configuration, by disposing a wedge between the second mirror member 30b and the slow-axis collimating lens 30c, the traveling direction of the laser beam L reflected by the second reflective surface 32b can be directed to the +X direction. The wedge may be disposed at a position where the laser beam L having exited from the slow-axis collimating lens 30c can be incident.

The wedge has a light incident surface and a light-emitting surface positioned on sides opposite to each other. The normal direction of the light incident surface is parallel to the −X direction, and the normal direction of a light-emitting surface is parallel to the XY plane, forms an acute angle with the +X direction, and forms an acute angle with the +Y direction or the −Y direction. Due to the light incident surface and the refraction at the light incident surface that are not parallel to each other, the wedge can change the traveling direction of the laser beams L transmitted through the wedge. However, when using the wedge, to direct the traveling direction of the laser beams L to the +X direction, a plurality of the wedges for which the normal directions of the light-emitting surfaces are mutually different need to be prepared to select the wedge having an appropriate normal direction of the light-emitting surface from the plurality of wedges.

On the other hand, in the light-emitting device 100 according to the first embodiment, disposing the second mirror member 30b in an appropriate position and orientation allows the traveling direction of the laser beam L reflected by the second reflective surface 32b to be directed to the +X direction. In the light-emitting device 100 according to the first embodiment, a plurality of the second mirror members 30b having mutually different angles between the upper surface and the inclined surface need not be prepared and the second mirror member 30b having an appropriate angle need not be selected from the plurality of second mirror members 30b.

The mirror members 30a and 30b illustrated in FIGS. 2B and 2C may each include, for example, a base having an inclined surface and a reflective surface separately formed on the inclined surface. The base may be formed of at least one material selected from the group consisting of glass, quartz, synthetic quartz, sapphire, ceramics, plastic, silicon, metal, silicone resin, and a dielectric material, for example. The reflective surface may be formed of a reflective material, such as a dielectric multilayer film or a metal material, for example. This reflective surface corresponds to the reflective surfaces 32a and 32b illustrated in FIGS. 2B and 2C.

Alternatively, the mirror members 30a and 30b may each include, for example, a base having an inclined surface, and the base may be formed of the above reflective material. In this case, the inclined surface of the base corresponds to the reflective surfaces 32a and 32b.

### Slow-axis Collimating Lens 30c

As illustrated in FIG. 2B, the slow-axis collimating lens 30c is supported by the upper surface 52 of the cover 50. As illustrated in FIG. 2H, the slow-axis collimating lens 30c is positioned away from the second reflective surface 32b in the +X direction. The slow-axis collimating lens 30c is a cylindrical lens having a uniform cross-sectional shape in the Z direction. The slow-axis collimating lens 30c is supported such that the focal point of the slow-axis collimating lens 30c substantially coincides with the center of the light emission point of the emission surface of the semiconductor laser element 22 illustrated in FIG. 2F. However, because the laser beam L is reflected by the first reflective surface 32a and the second reflective surface 32b in this order, the position of the focal point is adjusted in consideration of the fact that the optical path of the laser beam L is not a straight line but a polygonal line and/or an optical distance.

The laser beam L reflected by the first reflective surface 32a in the +Y direction is collimated in the YZ plane, but is not collimated in the XY plane. Therefore, the laser beam L reflected by the second reflective surface 32b in the +X direction travels while diverging in the XY plane as illustrated in FIG. 2H. A region surrounded by a broken line illustrated in FIG. 2H is a region where the intensity of the laser beam L is 1/e² or more of the peak intensity of the laser beam L in any plane perpendicular to the traveling direction of the laser beam L. e is the base of a natural logarithm.

The slow-axis collimating lens 30c collimates the laser beam L reflected by the second reflective surface 32b, in the slow axis direction in the XY plane. The slow axis direction of the laser beam L reflected by the second reflective surface 32b is parallel to the Y direction as illustrated in FIG. 2H. On the other hand, the slow axis direction of the laser beam L emitted from the laser light source 20 illustrated in FIG. 2F is parallel to the X direction. That is, the slow axis direction of the laser beam L reflected by the second reflective surface 32b intersects, more specifically is orthogonal to, the slow axis direction of the laser beam L emitted from the laser light source 20.

As illustrated in FIG. 2H, a second resin layer 34b exists between the lower surface of the slow-axis collimating lens 30c and the upper surface 52 of the cover 50. The second resin layer 34b is formed by curing uncured resin in a state in which the lower surface of the slow-axis collimating lens 30c is in contact with the upper surface 52 of the cover 50 via the resin. Before the resin is cured, the following active alignment is performed. That is, the position and orientation of the slow-axis collimating lens 30c are appropriately adjusted such that the slow-axis collimating lens 30c collimates the laser beam L in the slow axis direction with the laser light source 20 emitting the laser beam L. Such an adjustment may be performed while holding the slow-axis collimating lens 30c using a holding device after the light-emitting device 100 is disposed on the support surface 62 of the support base 60A illustrated in FIGS. 1A and 1B.

The slow-axis collimating lens 30c does not necessarily need to be supported by the cover 50 as long as the slow-axis collimating lens 30c is positioned away from the second reflective surface 32b in the +X direction. The light-emitting device 100 may include a support positioned on the +X direction side of the frame body 40, and the slow-axis collimating lens 30c may be supported by the support.

Alternatively, in the light-emitting module 200A illustrated in FIGS. 1A and 1B, when the traveling direction of the laser beam L emitted from the light-emitting device 100 is defined as the forward direction, the slow-axis collimating lens 30c of each of the light-emitting devices 100 other than the light-emitting device 100 on the foremost side may be supported by the cover 50 of the light-emitting device 100 on the immediately front side or the second mirror member 30b of the light-emitting device 100 on the immediately front side. The slow-axis collimating lens 30c of the light-emitting device 100 on the foremost side may be supported by the above support.

### Frame Body 40

The frame body 40 is positioned around the mounting surface 12 of the substrate 10 as illustrated in FIG. 2B, and supports the cover 50 as illustrated in FIG. 2A. As illustrated in FIG. 2B, the frame body 40 surrounds the laser light source 20 and the first mirror member 30a. As illustrated in FIG. 2C, the frame body 40 includes a protruding portion 43 protruding inward from an inner surface thereof. In the example illustrated in FIG. 2E, the protruding portion 43 protrudes toward both lateral surfaces and the back surface of the submount 21. The protruding portion 43 may further protrude toward the front surface of the submount 21. The protruding portion 43 may protrude only to both the lateral surfaces. The front surface of the submount 21 is positioned on the same side as the emission surface of the semiconductor laser element 22, and the back surface of the submount 21 is positioned on the side opposite to the emission surface of the semiconductor laser element 22. Both the lateral surfaces of the submount 21 join the front surface and the back surface of the submount 21.

As illustrated in FIG. 2C, the frame body 40 has a first upper surface 42a and a second upper surface 42b. The second upper surface 42b is an upper surface of the protruding portion 43, is positioned below the first upper surface 42a, and is surrounded by the first upper surface 42a in top view. As illustrated in FIG. 2E, the second upper surface 42b has a substantial U-shape.

The first upper surface 42a is provided with a first bonding region 46a and an outer region 47 surrounding the first bonding region 46a. Each of the first bonding region 46a and the outer region 47 has a substantially rectangular annular shape. The first bonding region 46a improves the bonding strength when the cover 50 is bonded to the frame body 40 via an inorganic bonding member such as a solder material. The outer region 47 reduces the possibility that the inorganic bonding member bonding the cover 50 may flow beyond the outer region 47. As illustrated in FIG. 2E, the first bonding region 46a and the outer region 47 surround the laser light source 20 and the first mirror member 30a in top view. A first conductive region 48a and a second conductive region 48b electrically insulated from each other are further provided, on the first upper surface 42a, on the −Z direction side of the first bonding region 46a and the outer region 47.

A third conductive region 48c and a fourth conductive region 48d electrically insulated from each other are provided on the second upper surface 42b. As illustrated in FIG. 2G, the third conductive region 48c is electrically connected to the first conductive region 48a via an internal wiring 45. Similarly, the fourth conductive region 48d is electrically connected to the second conductive region 48b via another internal wiring.

In the example illustrated in FIG. 2G, the internal wiring 45 includes a plurality of first portions that are in contact with the first conductive region 48a and extend in the Y direction, and a plurality of second portions that are in contact with the third conductive region 48c and extend in the Y direction. The number of first portions need not be plural and may be one. The same applies to the number of second portions. The internal wiring 45 further includes a third portion that is in contact with the plurality of first portions and the plurality of second portions and extends in the Z direction. However, the shapes of the first and second portions of the internal wiring 45 are not limited to the example illustrated in FIG. 2G. When the frame body 40 has a layered structure formed of a plurality of layers, the shapes of the first and second portions need not be linear, but rather may be stepped.

As illustrated in FIG. 2E, in top view, the laser light source 20 and the first mirror member 30a are positioned between a portion of the third conductive region 48c extending in the Z direction and a portion of the fourth conductive region 48d extending in the Z direction. The third conductive region 48c is electrically connected to the semiconductor laser element 22 via some wires 41 among the plurality of wires 41 illustrated in FIG. 2B. The fourth conductive region 48d is electrically connected to the semiconductor laser element 22 via an upper surface of the submount 21 and the remaining wires 41 illustrated in FIG. 2B. Therefore, by applying a voltage between the first conductive region 48a and the second conductive region 48b, electric power can be supplied to the laser light source 20.

As illustrated in FIG. 2D, the frame body 40 further has a first lower surface 44a and a second lower surface 44b. The second lower surface 44b partially has a lower surface of the protruding portion 43, is positioned above the first lower surface 44a, and is surrounded by the first lower surface 44a in bottom view as seen along the −Y direction. The second lower surface 44b has a substantially rectangular annular shape. Part or all of the substrate 10 illustrated in FIG. 2C is accommodated in a space surrounded by the step between the first lower surface 44a and the second lower surface 44b. When viewed through the frame body 40, an outer periphery of the second lower surface 44b surrounds an outer periphery of the mounting surface 12 of the substrate 10 in top view, and an inner periphery of the second lower surface 44b is surrounded by the outer periphery of the mounting surface 12 of the substrate 10 in top view.

A second bonding region 46b is provided on the entire first lower surface 44a. The second bonding region 46b improves the bonding strength when the support base 60A and the frame body 40 illustrated in FIGS. 1A and 1B are bonded to each other via an inorganic bonding member such as a solder material. A third bonding region 46c is provided on the entire second lower surface 44b. The third bonding region 46c is bonded to a peripheral edge region of the mounting surface 12 of the substrate 10 via an inorganic bonding member such as a brazing material. The third bonding region 46c improves the bonding strength when the substrate 10 and the frame body 40 are bonded to each other via the inorganic bonding member. The melting point of the brazing material is higher than the melting point of the solder material. Therefore, when the brazing material is heated to bond the substrate 10 and the frame body 40, and subsequently the solder material is heated to bond the substrate 10 and the laser light source 20, the possibility that the bonding of the substrate 10 and the frame body 40 may come undone due to the heat applied to the solder material can be reduced.

In the example illustrated in FIG. 2D, the second bonding region 46b is provided on the entire first lower surface 44a; however, the second bonding region 46b may be provided on a part of the first lower surface 44a. Similarly, in the example illustrated in FIG. 2D, the third bonding region 46c is provided on the entire second lower surface 44b; however, the third bonding region 46c may be provided on a part of the second lower surface 44b. Alternatively, the second bonding region 46b need not be provided on the first lower surface 44a, and the third bonding region 46c need not be provided on the second lower surface 44b. When the second bonding region 46b is not provided on the first lower surface 44a, the substrate 10 and the support base 60A are bonded only at the lower surface 14 of the substrate 10, without bonding the frame body 40 and the support base 60A.

In the example illustrated in FIG. 2F, the first lower surface 44a of the frame body 40 is positioned on the same plane as the lower surface 14 of the substrate 10. The first lower surface 44a of the frame body 40 may be positioned above the lower surface 14 of the substrate 10. Alternatively, the first lower surface 44a of the frame body 40 may be positioned below the lower surface 14 of the substrate 10 as long as the first lower surface 44a does not cause obstruction when bonding the substrate 10 and the support base 60A via the inorganic bonding member.

Like the support base 60A illustrated in FIGS. 1A and 1B, the frame body 40 may be formed of any of the above-described ceramics, for example. The size of the frame body 40 in the X direction may be in a range from 3 mm to 15 mm, for example, the maximum size thereof in the Y direction may be in a range from 1 mm to 5 mm, for example, and the size thereof in the Z direction may be in a range from 3 mm to 30 mm, for example.

The bonding regions 46a to 46c, the outer region 47, and the conductive regions 48a to 48d may each be formed of, for example, at least one metal material selected from the group consisting of Ag, Cu, W, Au, Ni, Pt, Pd, and the like. The bonding region 46a, the outer region 47, and the conductive regions 48a to 48d may each be formed by, for example, providing a metal film on the entire upper surfaces 42a and 42b and patterning the metal film by etching.

The wiring resistance value of the internal wiring 45 is preferably 5 mΩ or less, more preferably 1 mΩ or less. The internal wiring 45 is formed of a conductive material. The material of the internal wiring 45 is preferably CuW. In this case, the material of the substrate 10 may be Cu, for example, and the material of the frame body 40 may be AlN, for example.

### Cover 50

As illustrated in FIG. 2B, the cover 50 has an upper surface 52 and a lower surface 54. The lower surface 54 of the cover 50 faces the mounting surface 12 of the substrate 10, and the upper surface 52 of the cover 50 is positioned opposite to the lower surface 54 of the cover 50. In the present specification, the lower surface 54 of the cover 50 is also referred to as a “facing surface.” The cover 50 is positioned above the semiconductor laser element 22 and the first mirror member 30a.

The cover 50 functions as a sealing member that seals the laser light source 20 together with the substrate 10 and the frame body 40. The cover 50 further functions as a support member that supports the second mirror member 30b and the slow-axis collimating lens 30c.

The cover 50 transmits the laser beam L reflected by the first reflective surface 32a. More specifically, the cover 50 includes a light-transmitting portion 56 as illustrated in FIG. 2C, and the light-transmitting portion 56 transmits the laser beam L reflected by the first reflective surface 32a.

The cover 50 includes, on the lower surface 54, a light-shielding film 58 at least around the light-transmitting portion 56 through which the laser beam L is transmitted. In the example illustrated in FIG. 2C, the light-transmitting portion 56 has a rectangular shape, but is not limited to this shape. The shape of the light-transmitting portion 56 may be, for example, a circular shape or an elliptical shape.

Alternatively, the cover 50 may include, on the lower surface 54, the light-shielding film 58 on at least a part of the periphery of the light-transmitting portion 56. For example, when a part of an end of the light-transmitting portion 56 coincides with a part of an end of the lower surface 54, the light-shielding film 58 may be provided on at least a part of a region below on the lower surface 54. The region is a region, in the lower surface 54, adjacent to the remaining part other than the above part in the end of the light-transmitting portion 56.

The light-shielding film 58 reduces the possibility that stray light other than the laser beams L generated inside the light-emitting device 100 may leak to the outside of the light-emitting device 100. The light-shielding film 58 further reduces the possibility that, when the resin layers 34a and 34b illustrated in FIG. 2H are formed by the irradiation with ultraviolet rays or visible light, the ultraviolet rays or visible light may reach the laser light source 20. The light-shielding film 58 further reduces the possibility that return light of the laser beams L emitted to the outside of the light-emitting device 100 may reach the laser light source 20. When irradiation with the ultraviolet rays or the visible light, or the return light can be reduced, the laser light source 20 is less likely to be damaged.

In the example illustrated in FIG. 2C, the light-shielding film 58 is provided on the entire region, other than the light-transmitting portion 56, in the lower surface 54. The light-shielding film 58 provided in such a manner further reduces the possibility that the stray light may leak to the outside of the light-emitting device 100, and the possibility that the ultraviolet rays or the visible light, or the return light may reach the laser light source 20.

The light-transmitting portion 56 of the cover 50, which transmits the laser beam L, may have a transmittance for the laser beam L of equal to or greater than 60%, for example, and preferably have a transmittance for the laser beam L of equal to or greater than 80%. The remaining part of the cover 50 may have or need not have such light transmissivity.

Like, for example, the condensing lens 70A illustrated in FIGS. 1A and 1B, the cover 50 may be formed of any of the above-described light-transmissive materials. The size of the cover 50 in the X direction may be in a range from 3 mm to 15 mm, for example, the size thereof in the Y direction may be in a range from 0.1 mm to 1.5 mm, for example, and the size thereof in the Z direction may be in a range from 1 mm to 20 mm, for example.

The light-shielding film 58 may be formed of, for example, any of the above-described metal materials, like the bonding regions 46a to 46c, the outer region 47, and the conductive regions 48a to 48d. Like the bonding regions 46a to 46c, the outer region 47, and the conductive regions 48a to 48d, the light-shielding film 58 may be formed by, for example, providing a metal film on the entire lower surface 54 of the cover 50 and patterning the metal film by etching.

A peripheral region of the light-shielding film 58 is bonded to the first bonding region 46a provided on the first upper surface 42a of the frame body 40, via an inorganic bonding member such as a solder material. When the light-shielding film 58 is formed of any of the above metal materials, the light-shielding film 58 improves the bonding strength when the cover 50 and the frame body 40 are bonded to each other via the inorganic bonding member.

In the example illustrated in FIGS. 2A to 2C, the cover 50 has a flat plate shape, but is not limited to this shape. When the frame body 40 is removed from the light-emitting device 100, the substrate 10 may have a flat plate shape, and the cover 50 may have a box shape with an open lower portion. In the case of such a shape, the substrate 10 is bonded to the cover 50 such that the lower surface of the cover 50 is supported by the peripheral edge region of the mounting surface 12 of the substrate 10. Alternatively, in the light-emitting device 100, the cover 50 may have a box shape with an open lower portion. In the case of such a shape, the frame body 40 is bonded to the cover 50 such that the lower surface of the cover 50 is supported by the first upper surface 42a of the frame body 40.

As described above, the light-emitting device 100 according to the first embodiment can emit the laser beam L from above the space accommodating the semiconductor laser element 22. The emission direction of the laser beam L intersects, more specifically is orthogonal to, the direction in which each light-emitting device 100 has the largest size in the XZ plane. As a result, as described above, the plurality of light-emitting devices 100 can be disposed such that the distance between the optical axes of the plurality of laser beams L emitted from the plurality of light-emitting devices 100 is reduced.

The light-emitting device 100 according to the first embodiment can reduce the deviation between the traveling direction of the laser beam L emitted to the outside from the light-emitting device 100 and the +X direction being the designed traveling direction. As a result, in the light-emitting module 200A illustrated in FIGS. 1A and 1B, the plurality of laser beams L can be effectively combined by the condensing lens 70A and can be incident on the optical fiber 80.

The light-emitting device 100 may be manufactured in the following manner, for example. In an initial step, the substrate 10, the laser light source 20, the first mirror member 30a, the second mirror member 30b, the slow-axis collimating lens 30c, the frame body 40, the plurality of wires 41, and the cover 50 are prepared. In a subsequent step, the frame body 40 is bonded to the substrate 10. In a subsequent step, the laser light source 20 and the first mirror member 30a are provided on the mounting surface 12 of the substrate 10. In a subsequent step, the plurality of wires 41 for supplying electric power to the laser light source 20 are provided. In a subsequent step, the cover 50 is bonded to the frame body 40. In a subsequent step, active alignment is performed with the lower surface of the second mirror member 30b in contact with the upper surface 52 of the cover 50 via uncured resin. In a subsequent step, the resin is cured, and the first resin layer 34a is formed between the second mirror member 30b and the cover 50. In a subsequent step, active alignment is performed with the lower surface of the slow-axis collimating lens 30c in contact with the upper surface 52 of the cover 50 via uncured resin. In a subsequent step, the resin is cured, and the second resin layer 34b is formed between the slow-axis collimating lens 30c and the cover 50.

### Modified Example of Light-Emitting Device 100

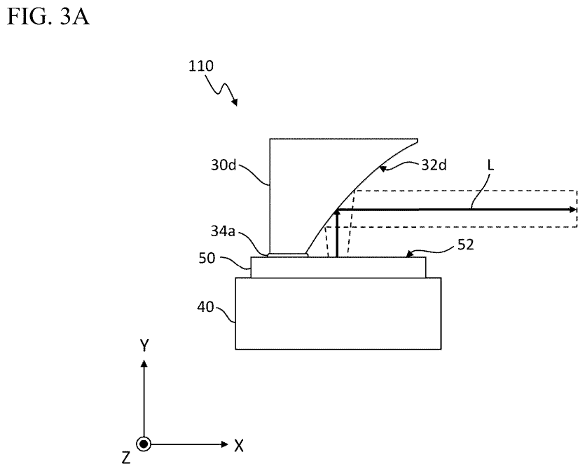

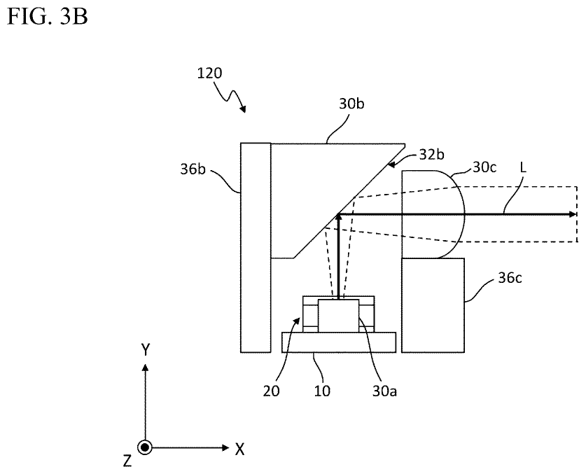

A first modified example and a second modified example of the light-emitting device 100 according to the first embodiment are described below with reference to FIGS. 3A and 3B. FIG. 3A is a side view schematically illustrating a configuration of the first modified example of the light-emitting device 100 according to the first embodiment, as seen along the +Z direction. A light-emitting device 110 illustrated in FIG. 3A is different from the light-emitting device 100 according to the first embodiment in that the light-emitting device 110 does not include the slow-axis collimating lens 30c illustrated in FIG. 2A and includes a second mirror member 30d illustrated in FIG. 3A instead of the second mirror member 30b illustrated in FIG. 2A.

The second mirror member 30d has a uniform cross-sectional shape in the Z direction. As illustrated in FIG. 3A, the second mirror member 30d has a second reflective surface 32d having a curved shape. The curve of the second reflective surface 32d in the XY plane may be, for example, a parabola. The second mirror member 30d is supported by the upper surface 52 of the cover 50 such that the focal point of the parabola substantially coincides with the center of the light emission point of the emission surface of the semiconductor laser element 22 illustrated in FIG. 2F. As a result, the second reflective surface 32d reflects the laser beam L, which is reflected by the first reflective surface 32a and travels in the +Y direction while diverging in the XY plane, in the +X direction in a state in which the laser beam Lis collimated in the slow axis direction in the XY plane as illustrated in FIG. 3A. When the curve of the second reflective surface 32d in the XY plane is a parabola, not only reducing the divergence of the laser beam L but also collimating the laser beam L can be performed. However, because the laser beam L is reflected by the first reflective surface 32a as illustrated in FIG. 2F, the position of the focal point is adjusted in consideration of the fact that the optical path of the laser beam L is not a straight line but a polygonal line and/or an optical distance.

In the light-emitting device 110, because the laser beam L reflected by the second reflective surface 32d is collimated, the slow-axis collimating lens 30c need not be separately provided. Therefore, in the light-emitting device 110, the number of components can be reduced. The curve of the second reflective surface 32d in the XY plane need not be a parabola as long as the laser beam L need not be collimated and the divergence of the laser beam L can be reduced.

FIG. 3B is a side view schematically illustrating a configuration of the second modified example of the light-emitting device 100 according to the first embodiment, as seen along the +Z direction. A light-emitting device 120 illustrated in FIG. 3B is different from the light-emitting device 100 according to the first embodiment in that the light-emitting device 120 includes a support member 36b and a support 36c instead of the frame body 40 and the cover 50. When the laser light source 20 need not be sealed, the frame body 40 and the cover 50 need not be provided. The support member 36b is disposed on the −X direction side of the laser light source 20, and supports the second mirror member 30b so as to be spaced apart from the first mirror member 30a. The support 36c is disposed on the +X direction side of the laser light source 20 and supports the slow-axis collimating lens 30c.

In the light-emitting device 120, the positions and orientations of the second mirror member 30b and the slow-axis collimating lens 30c can be appropriately adjusted by adjusting the positions and orientations of the support member 36b and the support 36c. Unlike in the light-emitting device 100, because the positions and orientations of the second mirror member 30b and the slow-axis collimating lens 30c need not be adjusted over the cover 50, the positions and orientations of the second mirror member 30b and the slow-axis collimating lens 30c can be easily adjusted.

### Second Embodiment

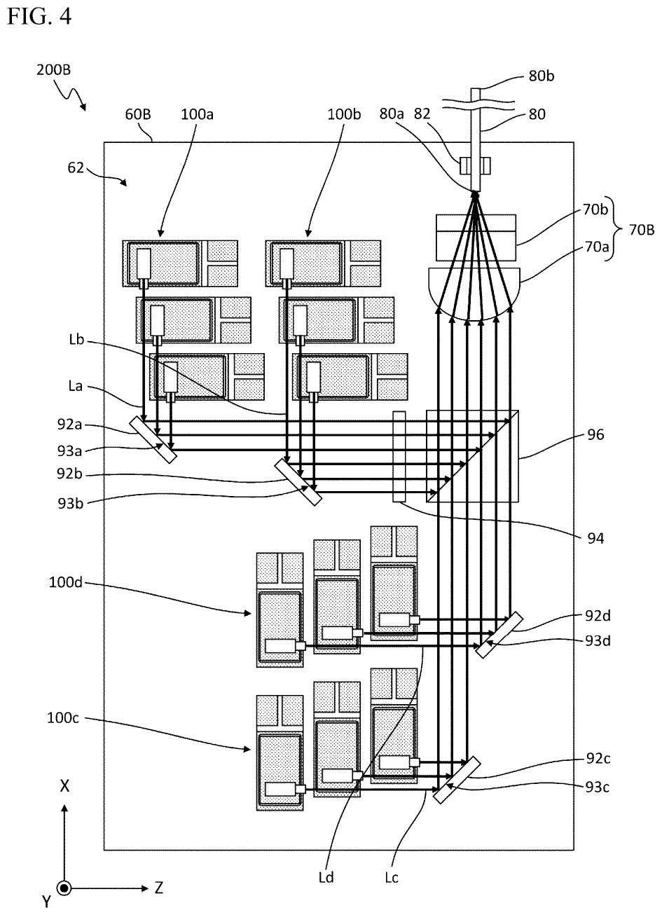

A configuration example of a light-emitting module according to a second embodiment of the present disclosure is described below with reference to FIG. 4. FIG. 4 is a top view schematically illustrating the configuration of the light-emitting module according to the second exemplary embodiment of the present disclosure. As described below, a light-emitting module 200B illustrated in FIG. 4 emits a high-power laser beam as compared with the light-emitting module 200A according to the first embodiment. The light-emitting module 200B illustrated in FIG. 4 is different from the light-emitting module 200A according to the first embodiment in the following four points.

The first point is that the light-emitting module 200B includes a plurality of light-emitting devices 100a, a plurality of light-emitting devices 100b, a plurality of light-emitting devices 100c, and a plurality of light-emitting devices 100d instead of the plurality of light-emitting devices 100 illustrated in FIGS. 1A and 1B. Each of the light-emitting devices 100a to 100d has the same structure as the light-emitting device 100. In the example illustrated in FIG. 4, the number of light-emitting devices 100a is three, but the number thereof may be two or four or more. The same applies to the number of light-emitting devices 100b to 100d.

The second point is that the light-emitting module 200B further includes mirror members 92a to 92d, a half-wave plate 94, and a polarizing beam splitter 96. The mirror member 92a has a reflective surface 93a, the mirror member 92b has a reflective surface 93b, the mirror member 92c has a reflective surface 93c, and the mirror member 92d has a reflective surface 93d.

The third point is that the light-emitting module 200B includes a condensing lens 70B instead of the condensing lens 70A illustrated in FIGS. 1A and 1B. The condensing lens 70B includes a fast-axis condensing lens 70a and a slow-axis condensing lens 70b. The fast-axis condensing lens 70a is a cylindrical lens having a uniform cross-sectional shape in the Y direction, and the slow-axis condensing lens 70b is a cylindrical lens having a uniform cross-sectional shape in the Z direction. The fast-axis condensing lens 70a has an optical axis parallel to the X direction, and causes light incident parallel to the optical axis to converge at a focal point of the fast-axis condensing lens 70a in the XZ plane. The slow-axis condensing lens 70b has an optical axis parallel to the X direction, and causes light incident parallel to the optical axis to converge at a focal point of the slow-axis condensing lens 70b in the XY plane. The material of the condensing lens 70B is the same as the material of the condensing lens 70A.

The fourth point is that the light-emitting module 200B includes a support base 60B instead of the support base 60A illustrated in FIGS. 1A and 1B. The number of components supported by the support base 60B is larger than the number of components supported by the support base 60A. Therefore, the size of the support base 60B in the X direction is larger than the size of the support base 60A in the X direction, and the size of the support base 60B in the Z direction is larger than the size of the support base 60A in the Z direction. The material of the support base 60B is the same as the material of the support base 60A.

The plurality of light-emitting devices 100a are arranged side by side in the X direction and are disposed at different positions in the Z direction on the support surface 62. In the example illustrated in FIG. 4, the plurality of light-emitting devices 100a are arranged side by side in the −X direction, and are disposed on the support surface 62 such that they are shifted stepwise in the +Z direction. The shift direction need not be the +Z direction, but rather may be the −Z direction, which is opposite to the +Z direction. Alternatively, the plurality of light-emitting devices 100a may be arranged side by side in the X direction and may be disposed irregularly in the Z direction. The arrangement of the plurality of light-emitting devices 100b is similar to the arrangement of the plurality of light-emitting devices 100a. The plurality of light-emitting devices 100b are adjacent to the plurality of light-emitting devices 100a in the Z direction. In the present specification, the direction in which the plurality of light-emitting devices 100a or the plurality of light-emitting devices 100b are disposed is also referred to as “one direction.”

The plurality of light-emitting devices 100c are arranged side by side in the Z direction and are disposed at different positions in the X direction on the support surface 62. In the example illustrated in FIG. 4, the plurality of light-emitting devices 100c are arranged side by side in the +Z direction, and are disposed on the support surface 62 such that they are shifted stepwise in the +X direction. The shift direction need not be the +X direction but may be the −X direction opposite to the +X direction. Alternatively, the plurality of light-emitting devices 100c may be arranged side by side in the Z direction and may be disposed irregularly in the X direction. The arrangement of the plurality of light-emitting devices 100d is similar to the arrangement of the plurality of light-emitting devices 100c. The plurality of light-emitting devices 100d are adjacent to the plurality of light-emitting devices 100c in the X direction. In the present specification, the direction in which the plurality of light-emitting devices 100c or the plurality of light-emitting devices 100d are disposed is also referred to as “another direction”.

Each of the light-emitting devices 100a emits a laser beam La in the −X direction. A traveling direction of the laser beam La is parallel to the direction in which the plurality of light-emitting devices 100a are disposed. Similarly, each of the light-emitting devices 100b emits a laser beam Lb in the −X direction. A traveling direction of the laser beam Lb is parallel to the direction in which the plurality of light-emitting devices 100b are disposed.

Each of the light-emitting devices 100c emits a laser beam Lc in the +Z direction. A traveling direction of the laser beam Lc is parallel to the direction in which the plurality of light-emitting devices 100c are disposed. Similarly, each of the light-emitting devices 100d emits a laser beam Ld in the +Z direction. A traveling direction of the laser beam Ld is parallel to the direction in which the plurality of light-emitting devices 100d are disposed.

The polarization directions of the laser beams La and Lb are the same as the polarization directions of the laser beams Lc and Ld. That is, an angle formed by each of the polarization directions of the laser beams Lc and Ld and the support surface 62 is the same as an angle formed by each of the polarization directions of the laser beams La and Lb and the support surface 62. The following is given on the assumption that the polarization directions of the laser beams La to Ld are parallel to the support surface 62.

The heights of optical axes of the plurality of laser beams La obtained when the laser beams La are emitted in the −X direction from the plurality of light-emitting devices 100a are equal to one another with the support surface 62 as a reference of the height. The same applies to the heights of optical axes of the plurality of laser beams Lb obtained when the laser beams Lb are emitted in the −X direction from the plurality of light-emitting devices 100b. The same applies to the heights of optical axes of the plurality of laser beams Lc obtained when the laser beams Lc are emitted in the +Z direction from the plurality of light-emitting devices 100c. The same applies to the heights of optical axes of the plurality of laser beams Ld obtained when the laser beams Ld are emitted in the +Z direction from the plurality of light-emitting devices 100d. The heights of the optical axes of the plurality of laser beams La to Ld are equal to one another.

The reflective surface 93a reflects the plurality of laser beams La and changes the traveling directions of the plurality of laser beams La to the +Z direction. The reflective surface 93b reflects the plurality of laser beams Lb and changes the traveling directions of the plurality of laser beams Lb to the +Z direction. The reflective surface 93c reflects the plurality of laser beams Lc and changes the traveling directions of the plurality of laser beams Lc to the +X direction. The reflective surface 93d reflects the plurality of laser beams Ld and changes the traveling directions of the plurality of laser beams Ld to the +X direction.

In the present specification, the laser beam La or the laser beam Lb is also referred to as a “first laser beam,” the mirror member 92a or the mirror member 92b that reflects the first laser beam is also referred to as a “third mirror member,” and the reflective surface of the third mirror member is also referred to as a “third reflective surface”. Similarly, the laser beam Lc or the laser beam Ld is also referred to as a “second laser beam,” the mirror member 92c or the mirror member 92d that reflects the second laser beam is also referred to as a “fourth mirror member,” and the reflective surface of the fourth mirror member is also referred to as a “fourth reflective surface”.

The half-wave plate 94 is positioned on the optical paths of the plurality of laser beams La and Lb, and rotates the polarization directions of the plurality of laser beams La and Lb by 90°. The polarization directions of the plurality of laser beams La and Lb are orthogonal to the polarization directions of the plurality of laser beams Lc and Ld.

The polarizing beam splitter 96 transmits P-polarized light and reflects S-polarized light. As described above, when the polarization directions of the laser beams La to Ld emitted from the light-emitting devices 100a to 100d are parallel to the support surface 62, the plurality of laser beams La and Lb having passed through the half-wave plate 94 are S-polarized light, and the plurality of laser beams Lc and Ld having not passed through the half-wave plate 94 are P-polarized light. Therefore, the polarizing beam splitter 96 reflects the plurality of laser beams La and Lb having passed through the half-wave plate 94 and transmits the plurality of laser beams Lc and Ld having not passed through the half-wave plate 94. As a result, the polarizing beam splitter 96 mixes the plurality of laser beams La and Lb having passed through the half-wave plate 94 and the plurality of laser beams Lc and Ld having not passed through the half-wave plate 94, and directs the mixed laser beams to the condensing lens 70B. The plurality of laser beams La to Ld having mixed with one another travel in the +X direction.

When the polarization directions of the laser beams La to Ld emitted from the light-emitting devices 100a to 100d are perpendicular to the support surface 62, the half-wave plate 94 is positioned on the optical paths of the plurality of laser beams Lc and Ld and rotates the polarization directions of the plurality of laser beams Lc and Ld by 90°. The plurality of laser beams La and Lb having not passed through the half-wave plate 94 are S-polarized light, and the laser beams Lc and Ld having passed through the half-wave plate 94 are P-polarized light. The polarizing beam splitter 96 reflects the plurality of laser beams La and Lb having not passed through the half-wave plate 94, and transmits the plurality of laser beams Lc and Ld having passed through the half-wave plate 94. As a result, the polarizing beam splitter 96 mixes the plurality of laser beams La and Lb having not passed through the half-wave plate 94 and the plurality of laser beams Lc and Ld having passed through the half-wave plate 94, and directs the mixed laser beams to the condensing lens 70B. The plurality of laser beams La to Ld having mixed with one another travel in the +X direction.

The fast-axis condensing lens 70a included in the condensing lens 70B is disposed such that the focal point of the fast-axis condensing lens 70a substantially coincides with the light-incident end 80a of the optical fiber 80. The same applies to the arrangement of the slow-axis condensing lens 70b. The fast-axis condensing lens 70a and the slow-axis condensing lens 70b cause the plurality of laser beams La to Ld traveling in the +X direction to converge at the light-incident end 80a of the optical fiber 80. In this way, the condensing lens 70B can combine the plurality of laser beams La to Ld and cause the combined laser beams to enter the optical fiber 80. The optical fiber 80 guides the plurality of laser beams La to Ld combined by the condensing lens 70B and causes the laser beams to exit from the light-emitting end 80b.

As described above, the light-emitting module 200B emits, from the light-emitting end 80b of the optical fiber 80, combined light obtained by combining the plurality of laser beams La to Ld. In the light-emitting module 200B, the number of light-emitting devices 100a to 100d can be increased as compared with the light-emitting module 200A illustrated in FIGS. 1A and 1B. Because the output of the combined light can be increased by increasing the number of light-emitting devices 100a to 100d, the light-emitting module 200B can emit a high-power laser beam as compared with the light-emitting module 200A.

In the light-emitting module 200B, when the traveling direction of each of the laser beams La emitted from the plurality of light-emitting devices 100a is defined as a forward direction, the laser beam La emitted from each of the light-emitting devices 100a other than the light-emitting device 100a positioned on the foremost side travels without hitting the light-emitting device 100a disposed further forward as illustrated in FIG. 4. Therefore, the plurality of light-emitting devices 100a need not be disposed at different heights such that the laser beams La do not interfere with each other. As illustrated in FIG. 4, the plurality of light-emitting devices 100a can be disposed on the same plane such that the distance between the optical axes of the plurality of laser beams La is reduced, even without providing a step on the support surface 62 of the support base 60B. The plurality of light-emitting devices 100a are disposed on the same plane, thereby reducing variations in the amount of heat generated from the plurality of light-emitting devices 100a and transferred to the plane on which the support base 60B is disposed. The same applies to the plurality of light-emitting devices 100b, the plurality of light-emitting devices 100c, and the plurality of light-emitting devices 100d.

### Modified Example of Light-Emitting Module 200B

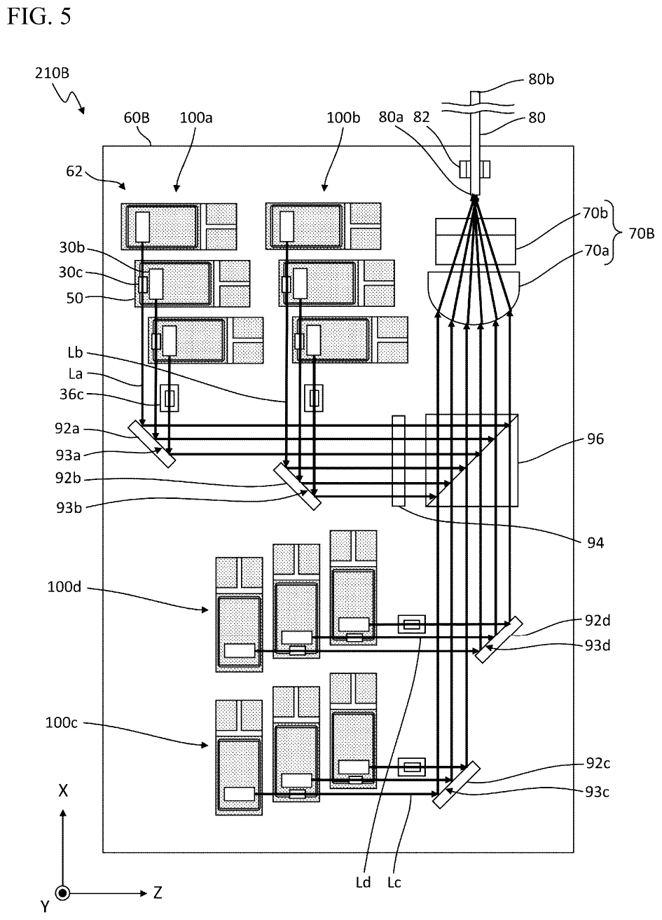

A modified example of the light-emitting module 200B according to the second embodiment is described below with reference to FIG. 5. FIG. 5 is a top view schematically illustrating the modified example of the light-emitting module 200B according the second embodiment. A light-emitting module 210B illustrated in FIG. 5 is different from the light-emitting module 200B according to the second embodiment in the following points. The slow-axis collimating lens 30c of each of the plurality of light-emitting devices 100 other than the light-emitting device 100a on the foremost side is supported by the cover 50 of the light-emitting device 100 on the immediately front side. The slow-axis collimating lens 30c may be supported by the second mirror member 30b. The light-emitting device 100a on the foremost side further includes the support 36c, and the slow-axis collimating lens 30c of the light-emitting device 100a on the foremost side is supported by the support 36c. The same applies to the plurality of light-emitting devices 100b, the plurality of light-emitting devices 100c, and the plurality of light-emitting devices 100d.

In the light-emitting module 210B, as compared with the light-emitting module 200B, after components other than a plurality of slow-axis collimating lenses 30c are disposed, the plurality of slow-axis collimating lenses 30c are easily disposed, for the plurality of light-emitting devices 100a. Therefore, each slow-axis collimating lens 30 is easily adjusted to an appropriate position and orientation. The same applies to the plurality of light-emitting devices 100b, the plurality of light-emitting devices 100c, and the plurality of light-emitting devices 100d.

### Configuration of Laser Light Source 20

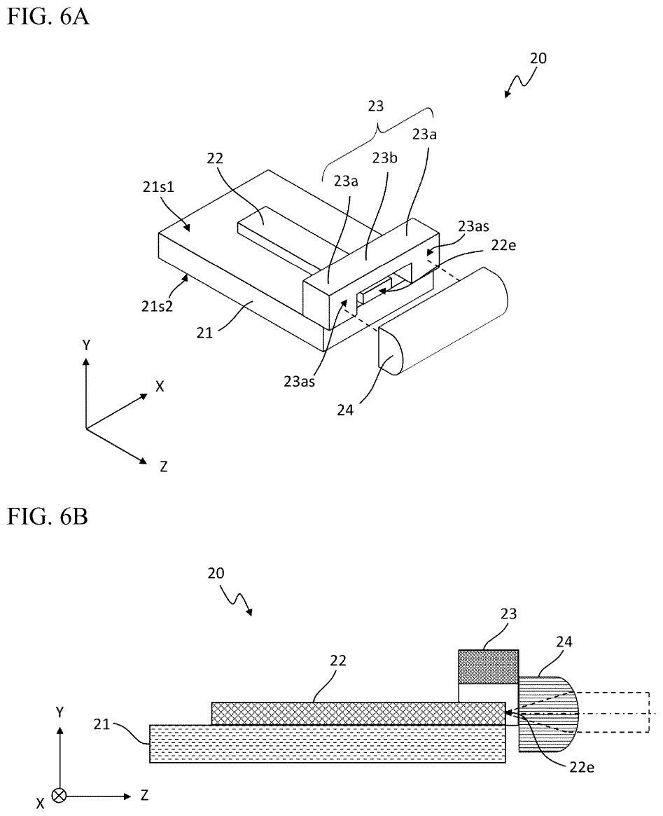

An example of a configuration of the laser light source 20 illustrated in FIG. 2C is described below with reference to FIGS. 6A and 6B. FIG. 6A is an exploded perspective view of the laser light source 20. FIG. 6B is a cross-sectional view of the laser light source 20 parallel to the YZ plane. Each of the components of the laser light source 20 is described below.

As illustrated in FIG. 6A, the submount 21 has an upper surface 21s1 and a lower surface 21s2 parallel to the XZ plane. A metal film is provided on each of the upper surface 21s1 and the lower surface 21s2. The metal film provided on the upper surface 21s1 improves the bonding strength when the semiconductor laser element 22 and the lens support member 23 are bonded to the submount 21 via an inorganic bonding member. The metal film provided on the upper surface 21s1 may further be used for supplying electric power to the semiconductor laser element 22. The metal film provided on the lower surface 21s2 improves the bonding strength when the substrate 10 and the laser light source 20 illustrated in FIG. 2C are bonded to each other via an inorganic bonding member. The metal film provided on each of the upper surface 21s1 and the lower surface 21s2 also serves to transfer heat generated in the semiconductor laser element 22 during driving to the substrate 10 via the submount 21. Like the support base 60A illustrated in FIGS. 1A and 1B, the submount 21 may be formed of any of the ceramics, the metal materials, and the metal-matrix composite materials described above, for example.

As illustrated in FIG. 6A, the semiconductor laser element 22 is supported by the upper surface 21s1 of the submount 21. The semiconductor laser element 22 has the emission surface 22e on one of two end surfaces intersecting the Z direction, and emits the laser beam from the emission surface 22e in the +Z direction. The laser beam diverges at different speeds in the YZ plane and the XZ plane as it travels in the +Z direction. The laser beam diverges relatively fast in the YZ plane and relatively slow in the XZ plane. When the laser beam is not collimated, the spot of the laser beam has an elliptical shape having a major axis in the Y direction and a minor axis in the X direction in the XY plane in the far field.

The semiconductor laser element 22 can emit a violet, blue, green, or red laser beam in the visible region or an infrared or ultraviolet laser beam in the invisible region. The light emission peak wavelength of the violet light is preferably in a range from 400 nm to 420 nm and more preferably in a range from 400 nm to 415 nm. The light emission peak wavelength of the blue light is preferably in a range from more than 420 nm to 495 nm and more preferably in a range from 440 nm to 475 nm. The light emission peak wavelength of the green light is preferably in a range from more than 495 nm to 570 nm and more preferably in a range from 510 nm to 550 nm. The light emission peak wavelength of the red light is preferably in a range from 605 nm to 750 nm and more preferably in a range from 610 nm to 700 nm.

Examples of the semiconductor laser element 22 that emits a violet, blue, and green laser beam include laser diodes containing a nitride semiconductor material. For example, GaN, InGaN, and AlGaN can be used as the nitride semiconductor material.

Examples of the semiconductor laser element 22 that emits a red laser beam include a laser diode containing an InAlGaP-based, GaInP-based, GaAs-based, or AlGaAs-based semiconductor material.

As illustrated in FIG. 6A, the lens support member 23 is supported by the upper surface 21s1 of the submount 21. The lens support member 23 includes two columnar portions 23a and a coupling portion 23b that is positioned between the two columnar portions 23a and couples the two columnar portions 23a. The two columnar portions 23a are positioned on both sides of the semiconductor laser element 22, and the coupling portion 23b is positioned above the emission surface 22e side of the semiconductor laser element 22. The lens support member 23 supports the fast-axis collimating lens 24 using end surfaces 23as of the two columnar portions 23a. The lens support member 23 is positioned straddling the semiconductor laser element 22 and does not obstruct the laser beam emitted from the semiconductor laser element 22 from being incident on the fast-axis collimating lens 24.

Like the support base 60A illustrated in FIGS. 1A and 1B, the lens support member 23 may be formed of any of the above-described ceramics, for example. Like the condensing lens 70A illustrated in FIGS. 1A and 1B, the lens support member 23 may be formed of any of the above-described light-transmissive materials, for example. The lens support member 23 may be formed of at least one alloy selected from the group consisting of kovar and CuW, for example. The lens support member 23 may be formed of Si, for example.

As illustrated in FIG. 6A, the fast-axis collimating lens 24 may be, for example, a cylindrical lens having a uniform cross-sectional shape in the X direction. The fast-axis collimating lens 24 has a flat surface on a light incident side and a convex curved surface on a light-emitting side. The convex curved surface has a curvature in the YZ plane. The focal point of the fast-axis collimating lens 24 substantially coincides with a center of a light emission point of the emission surface 22e of the semiconductor laser element 22. As illustrated in FIG. 6B, the fast-axis collimating lens 24 collimates the laser beam emitted in the +Z direction from the emission surface 22e of the semiconductor laser element 22, in the fast axis direction in the YZ plane. A region surrounded by a broken line illustrated in FIG. 6B represents a region where the intensity of the laser beam is 1/e² times or more of the peak intensity thereof. Like the condensing lens 70A illustrated in FIGS. 1A and 1B, the fast-axis collimating lens 24 may be formed of any of the above-described light-transmissive materials, for example.

In order to collimate the laser beam L before the laser beam L widely diverges, the fast-axis collimating lens 24 is positioned near the emission surface 22e of the semiconductor laser element 22 and between the mounting surface 12 of the substrate 10 and the lower surface 54 of the cover 50, and is positioned on the optical path of the laser beam L as illustrated in FIG. 2F. Because the fast-axis collimating lens 24 is disposed inside a sealed space formed by the substrate 10, the frame body 40, and the cover 50, the light-emitting device 100 can be reduced in size.

Instead of the fast-axis collimating lens 24, a collimating lens may be used that collimates the laser beam L emitted from the semiconductor laser element 22 not only in the YZ plane but also in the XZ plane. In this case, the light-emitting device 100 illustrated in FIG. 2A need not be provided with the slow-axis collimating lens 30c.

A light-emitting device of the present disclosure can be particularly used for combining a plurality of laser beams to achieve a high-power laser beam. The light-emitting device of the present disclosure can be used for industrial fields requiring a high-power laser light source, such as cutting, drilling, local heat treatment, surface treatment, metal welding, and 3D printing of various materials.

1. A light-emitting device comprising:
a substrate having a mounting surface;
a semiconductor laser element supported by the mounting surface;
a first mirror member supported by the mounting surface and having a first reflective surface inclined with respect to the mounting surface and facing obliquely upward; and
a second mirror member supported by a support member such that the second mirror member is spaced apart from the first mirror member, the second mirror member having a second reflective surface at least a part of which is positioned above at least a part of the first reflective surface, wherein:
the semiconductor laser element is configured to emit a laser beam toward the first reflective surface in a first direction,
the first reflective surface reflects the laser beam to change a traveling direction of the laser beam to a second direction away from the mounting surface of the substrate, and
the second reflective surface reflects the laser beam reflected by the first reflective surface to change the traveling direction of the laser beam to a third direction that intersects a plane in which both a straight line extending in the first direction and a straight line extending in the second direction extend.

2. The light-emitting device according to claim 1, wherein:
the support member is a cover having a facing surface facing the mounting surface of the substrate and an upper surface positioned opposite to the facing surface, the cover being positioned above the semiconductor laser element and the first mirror member,
the second mirror member is supported by the upper surface of the cover, and
the cover transmits the laser beam reflected by the first reflective surface.

3. The light-emitting device according to claim 2, further comprising a resin layer located between a lower surface of the second mirror member and the upper surface of the cover.

4. The light-emitting device according to claim 2, wherein the cover comprises, on the facing surface of the cover, a light-shielding film at least around a portion through which the laser beam is transmitted.

5. The light-emitting device according to claim 2, further comprising:
a fast-axis collimating lens positioned between the mounting surface of the substrate and the facing surface of the cover and positioned on an optical path of the laser beam, wherein:
the fast-axis collimating lens is configured to collimate the laser beam emitted from the semiconductor laser element, in a fast axis direction.

6. The light-emitting device according to claim 1, further comprising:
a slow-axis collimating lens positioned away from the second reflective surface in the third direction, wherein:
the slow-axis collimating lens is configured to collimate the laser beam reflected by the second reflective surface, in a slow axis direction, and
the slow axis direction of the laser beam reflected by the second reflective surface intersects a slow axis direction of the laser beam emitted from the semiconductor laser element.

7. The light-emitting device according to claim 1, wherein:
the second reflective surface is a reflective surface having a curved shape, and reflects the laser beam reflected by the first reflective surface in the third direction in a state in which the laser beam is collimated in a slow axis direction, and
the slow axis direction of the laser beam reflected by the second reflective surface intersects a slow axis direction of the laser beam emitted from the semiconductor laser element.

8. The light-emitting device according to claim 1, wherein the substrate is formed of a material having a thermal conductivity in a range from 10 W/m·K to 2000 W/m·K.

9. The light-emitting device according to claim 2, further comprising:
a frame body positioned around the mounting surface of the substrate and supporting the cover, wherein:
the semiconductor laser element is sealed by the substrate, the frame body, and the cover.

10. A light-emitting module comprising:
a plurality of light-emitting devices arranged side by side in the third direction and disposed such that the plurality of light-emitting devices are shifted stepwise in a direction the same as or opposite to the first direction, each of the plurality of light-emitting devices being the light-emitting device according to claim 1; and
a condensing lens configured to combine a plurality of laser beams obtained when the laser beam is emitted from each of the plurality of light-emitting devices in the third direction.

11. The light-emitting module according to claim 10, wherein the plurality of light-emitting devices are disposed on a same plane.

12. A light-emitting module comprising:
a plurality of first light-emitting devices disposed at different positions in one direction, each of the plurality of light-emitting devices being the light-emitting device according to claim 1 that is configured to emit a first laser beam in a direction parallel to the one direction;
a plurality of second light-emitting devices disposed at different positions in another direction, each of the plurality of light-emitting devices being the light-emitting device according to claim 1 that is configured to emit a second laser beam in a direction parallel to the another direction;
a third mirror member having a third reflective surface, the third reflective surface being configured to reflect a plurality of first laser beams obtained when the first laser beam is emitted from each of the plurality of first light-emitting devices;
a fourth mirror member having a fourth reflective surface, the fourth reflective surface being configured to reflect a plurality of second laser beams obtained when the second laser beam is emitted from each of the plurality of second light-emitting devices; and
a condensing lens configured to combine the plurality of first laser beams reflected by the third reflective surface and the plurality of second laser beams reflected by the fourth reflective surface.

13. The light-emitting module according to claim 12, wherein:
a polarization direction of the second laser beam in each of the plurality of second light-emitting devices is same as a polarization direction of the first laser beam in each of the plurality of first light-emitting devices, and
the light-emitting module further comprises:
a half-wave plate positioned on optical paths of the plurality of first laser beams or optical paths of the plurality of second laser beams; and
a polarizing beam splitter configured to mix (i) the plurality of first laser beams that have passed through the half-wave plate and the plurality of second laser beams that have not passed through the half-wave plate, or (ii) the plurality of first laser beams that have not passed through the half-wave plate and the plurality of second laser beams that have passed through the half-wave plate, and to direct the mixed laser beams to the condensing lens.
